(19) United States
(12) Patent Application Publication
(10) Pub. No.: US 2021/0013859 A1
(43) Pub. Date: Jan. 14, 2021

(54) TRANSVERSELY-EXCITED FILM BULK ACOUSTIC RESONATOR WITH ETCHED CONDUCTOR PATTERNS

(71) Applicant: Resonant Inc., Goleta, CA (US)

(72) Inventors: Patrick Turner, San Bruno, CA (US); Ryo Wakabayashi, Santa Clara, CA (US)

(21) Appl. No.: 17/027,610

(22) Filed: Sep. 21, 2020

Related U.S. Application Data
(63) Continuation-in-part of application No. 16/920,173, filed on Jul. 2, 2020.
Application No. 16/920,173 is a continuation of application No. 16/438,121, filed on Jun. 11, 2019, now Pat. No. 10,756,697.
Application No. 16/438,121 is a continuation-in-part of application No. 16/230,443, filed on Dec. 21, 2018, now Pat. No. 10,491,192.
(60) Provisional application No. 62/685,825, filed on Jun. 15, 2018.
(60) Provisional application No. 62/701,363, filed on Jul. 20, 2018.
(60) Provisional application No. 62/741,702, filed on Oct. 5, 2018.
(60) Provisional application No. 62/748,883, filed on Oct. 22, 2018.
(60) Provisional application No. 62/753,815, filed on Oct. 31, 2018.
(60) Provisional application No. 63/019,749, filed on May 4, 2020.

(51) Int. Cl. H03H 9/02; H03H 3/04; H03H 9/13; H03H 9/17; H03H 9/56

(52) U.S. Cl. CPC H03H 9/02228; H03H 3/04; H03H 9/02031; H03H 9/132; H03H 9/174; H03H 2003/023; H03H 9/564; H03H 9/568; H03H 9/176; H03H 2003/0442; H03H 9/562

(57) ABSTRACT

An acoustic resonator includes a substrate having a surface and a single-crystal piezoelectric plate having a back surface bonded to the substrate. An interdigital transducer (IDT) is formed on the front surface of the piezoelectric plate and has interleaved fingers on a diaphragm spanning a cavity in the substrate. An etch-stop layer is formed on the front surface of the piezoelectric plate between the interleaved fingers. A portion of the piezoelectric plate and the etch-stop layer form the diaphragm. The etch-stop layer is impervious to the etch process used to form the interleaved fingers. The etch-stop layer may be formed on the piezoelectric plate between but not under the interleaved fingers. In other cases, the etch-stop layer is formed on the piezoelectric plate between and under the interleaved fingers.

### RELATED APPLICATION INFORMATION

The patent claims priority to provisional patent application 63/019,749, titled ETCH STOP LAYER TO ENABLE DEP-ETCH OF IDTS, filed May 4, 2020.

This patent is a continuation-in-part of application Ser. No. 16/920,173, titled TRANSVERSELY-EXCITED FILM BULK ACOUSTIC RESONATOR, filed Jul. 2, 2020, which is a continuation of application Ser. No. 16/438,121 titled TRANSVERSELY-EXCITED FILM BULK ACOUSTIC RESONATOR, filed Jun. 11, 2019, which is a continuation-in-part of application Ser. No. 16/230,443, entitled TRANSVERSELY-EXCITED FILM BULK ACOUSTIC RESONATOR, filed Dec. 21, 2018, now U.S. Pat. No. 10,491,192, which claims priority from the following provisional patent applications: application 62/685,825, filed Jun. 15, 2018, entitled SHEAR-MODE FBAR (XBAR); application 62/701,363, filed Jul. 20, 2018, entitled SHEAR-MODE FBAR (XBAR); application 62/741,702, filed Oct. 5, 2018, entitled 5 GHZ LATERALLY-EXCITED BULK WAVE RESONATOR (XBAR); application 62/748,883, filed Oct. 22, 2018, entitled SHEAR-MODE FILM BULK ACOUSTIC RESONATOR; and application 62/753,815, filed Oct. 31, 2018, entitled LITHIUM TANTALATE SHEAR-MODE FILM BULK ACOUSTIC RESONATOR.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to radio frequency filters using acoustic wave resonators, and specifically to filters for use in communications equipment.

### Description of the Related Art

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a passband or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

The desire for wider communication channel bandwidths will inevitably lead to the use of higher frequency communications bands. The current LTE™ (Long Term Evolution) specification defines frequency bands from 3.3 GHz to 5.9 GHz. These bands are not presently used. Future proposals for wireless communications include millimeter wave communication bands with frequencies up to 28 GHz.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies proposed for future communications networks.

### DESCRIPTION OF THE DRAWINGS

FIG. 1 includes a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3 is an alternative schematic cross-sectional view of the XBAR of FIG. 1.

FIG. 4 is a graphic illustrating a shear horizontal acoustic mode in an XBAR.

FIG. 5 is a schematic block diagram of a filter using XBARs.

FIG. 6 is an expanded schematic cross-sectional view of a portion of an XBAR with an etch-stop layer.

FIG. 7 is an expanded schematic cross-sectional view of a portion of another XBAR with an etch-stop layer.

FIG. 8 is a flow chart of a process for fabricating an XBAR.

FIG. 9A and FIG. 9B are collectively a flow chart of a process for forming a conductor pattern using dry etching and an etch-stop layer.

FIG. 10A and FIG. 10B are collectively a flow chart of another process for forming a conductor pattern using dry etching and an etch-stop layer.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

Description of Apparatus

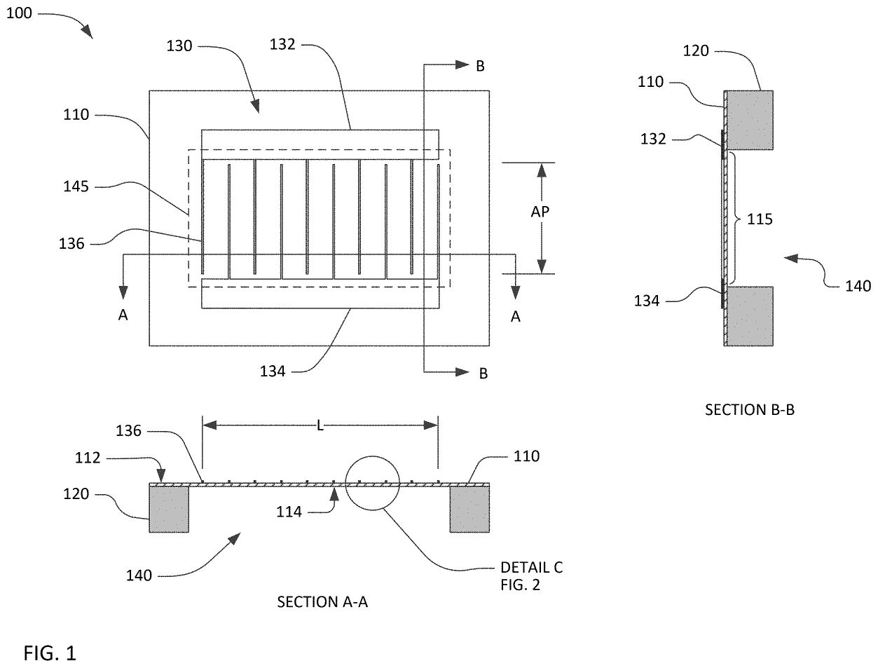

FIG. 1 shows a simplified schematic top view and orthogonal cross-sectional views of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the front and back surfaces 112, 114. However, XBARs may be fabricated on piezoelectric plates with other crystallographic orientations.

The back surface 114 of the piezoelectric plate 110 is attached to a surface of the substrate 120 except for a portion of the piezoelectric plate 110 that forms a diaphragm 115 spanning a cavity 140 formed in the substrate. The portion of the piezoelectric plate that spans the cavity is referred to herein as the “diaphragm” 115 due to its physical resemblance to the diaphragm of a microphone. As shown in FIG. 1, the diaphragm 115 is contiguous with the rest of the piezoelectric plate 110 around all of a perimeter 145 of the cavity 140. In this context, “contiguous” means “continuously connected without any intervening item”.

The substrate 120 provides mechanical support to the piezoelectric plate 110. The substrate 120 may be, for example, silicon, sapphire, quartz, or some other material or combination of materials. The back surface 114 of the piezoelectric plate 110 may be bonded to the substrate 120 using a wafer bonding process. Alternatively, the piezoelectric plate 110 may be grown on the substrate 120 or attached to the substrate in some other manner. The piezoelectric plate 110 may be attached directly to the substrate or may be attached to the substrate 120 via one or more intermediate material layers.

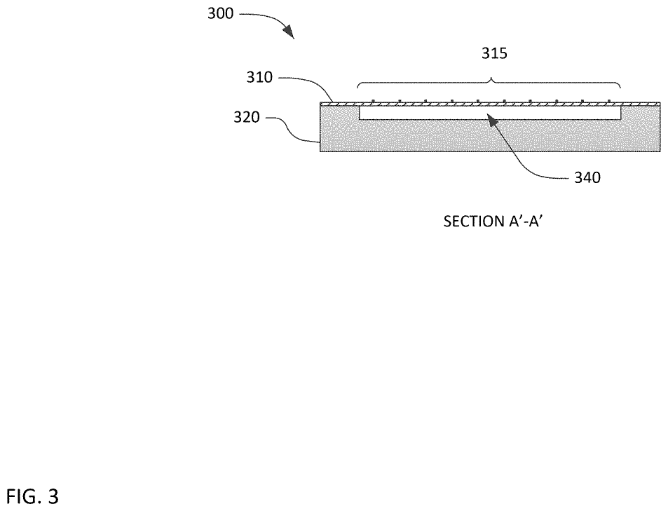

“Cavity” has its conventional meaning of “an empty space within a solid body.” The cavity 140 may be a hole completely through the substrate 120 (as shown in Section A-A and Section B-B) or a recess in the substrate 120 (as shown subsequently in FIG. 3A and FIG. 3B). The cavity 140 may be formed, for example, by etching a portion of the substrate 120 to form a separate cavity for a resonator, before or after the piezoelectric plate 110 and the substrate 120 are attached. This etch may be selective by having a chemistry to etch the material of the substrate but not the material piezoelectric plate.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. As will be discussed in further detail, the primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

The IDT 130 is positioned on the piezoelectric plate 110 such that at least the fingers of the IDT 130 are disposed on the portion 115 of the piezoelectric plate that spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds, possibly thousands, of parallel fingers in the IDT 110. Similarly, the thickness of the fingers in the cross-sectional views is greatly exaggerated.

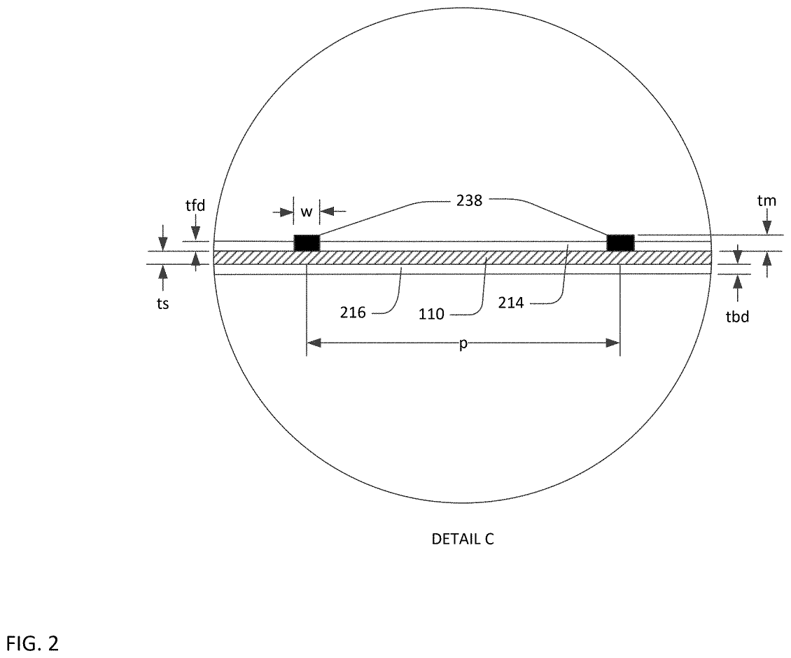

FIG. 2 shows a detailed schematic cross-sectional view of the XBAR 100. The piezoelectric plate 110 is a single-crystal layer of piezoelectrical material having a thickness ts. ts may be, for example, 100 nm to 1500 nm. When used in filters for LTE™ bands from 3.4 GHZ to 6 GHz (e.g. bands 42, 43, 46), the thickness ts may be, for example, 200 nm to 1000 nm.

A front-side dielectric layer 214 may optionally be formed on the front side of the piezoelectric plate 110. The “front side” of the XBAR is, by definition, the surface facing away from the substrate. The front-side dielectric layer 214 has a thickness tfd. The front-side dielectric layer 214 is formed between the IDT fingers 238. Although not shown in FIG. 2, the front side dielectric layer 214 may also be deposited over the IDT fingers 238. A back-side dielectric layer 216 may optionally be formed on the back side of the piezoelectric plate 110. The back-side dielectric layer 216 has a thickness tbd. The front-side and back-side dielectric layers 214, 216 may be a non-piezoelectric dielectric material, such as silicon dioxide or silicon nitride. tfd and tbd may be, for example, 0 to 500 nm. tfd and tbd are typically less than the thickness ts of the piezoelectric plate. tfd and tbd are not necessarily equal, and the front-side and back-side dielectric layers 214, 216 are not necessarily the same material. Either or both of the front-side and back-side dielectric layers 214, 216 may be formed of multiple layers of two or more materials.

The IDT fingers 238 may be aluminum, a substantially aluminum alloys, copper, a substantially copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric plate 110 and/or to passivate or encapsulate the fingers. The busbars (132, 134 in FIG. 1) of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers. The IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e. the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness is of the piezoelectric slab 212. The width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

FIG. 3 is an alternative cross-sectional view along the section plane A-A defined in FIG. 1. In FIG. 3, a piezoelectric plate 310 is attached to a substrate 320. A portion of the piezoelectric plate 310 forms a diaphragm 315 spanning a cavity 340 in the substrate. The cavity 340 does not fully penetrate the substrate 320. Fingers of an IDT are disposed on the diaphragm 315. The cavity 340 may be formed, for example, by etching the substrate 320 before attaching the piezoelectric plate 310. Alternatively, the cavity 340 may be formed by etching the substrate 320 with a selective etchant that reaches the substrate through one or more openings (not shown) provided in the piezoelectric plate 310. In this case, the diaphragm 315 may be contiguous with the rest of the piezoelectric plate 310 around a large portion of a perimeter 345 of the cavity 340. For example, the diaphragm 315 may be contiguous with the rest of the piezoelectric plate 310 around at least 50% of the perimeter 345 of the cavity 340.

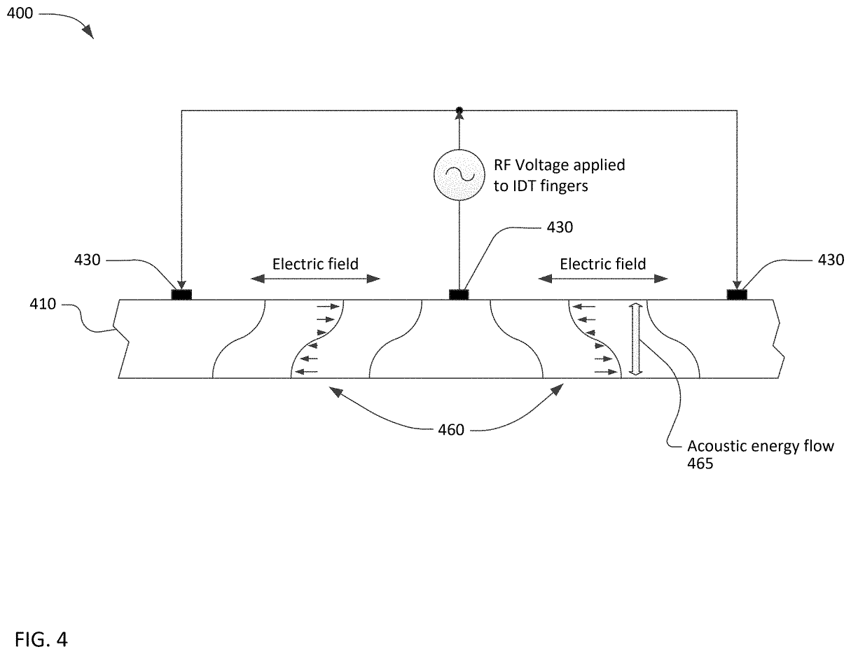

FIG. 4 is a graphical illustration of the primary acoustic mode of interest in an XBAR. FIG. 4 shows a small portion of an XBAR 400 including a piezoelectric plate 410 and three interleaved IDT fingers 430. An RF voltage is applied to the interleaved fingers 430. This voltage creates a time-varying electric field between the fingers. The direction of the electric field is lateral, or parallel to the surface of the piezoelectric plate 410, as indicated by the arrows labeled “electric field”. Due to the high dielectric constant of the piezoelectric plate, the electric field is highly concentrated in the plate relative to the air. The lateral electric field introduces shear deformation, and thus strongly excites a primary shear-mode acoustic mode, in the piezoelectric plate 410. In this context, “shear deformation” is defined as deformation in which parallel planes in a material remain parallel and maintain a constant distance while translating relative to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. The degree of atomic motion, as well as the thickness of the piezoelectric plate 410, have been greatly exaggerated for ease of visualization. While the atomic motions are predominantly lateral (i.e. horizontal as shown in FIG. 4), the direction of acoustic energy flow of the excited primary shear acoustic mode is substantially orthogonal to the surface of the piezoelectric plate, as indicated by the arrow 465.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. High piezoelectric coupling enables the design and implementation of microwave and millimeter-wave filters with appreciable bandwidth.

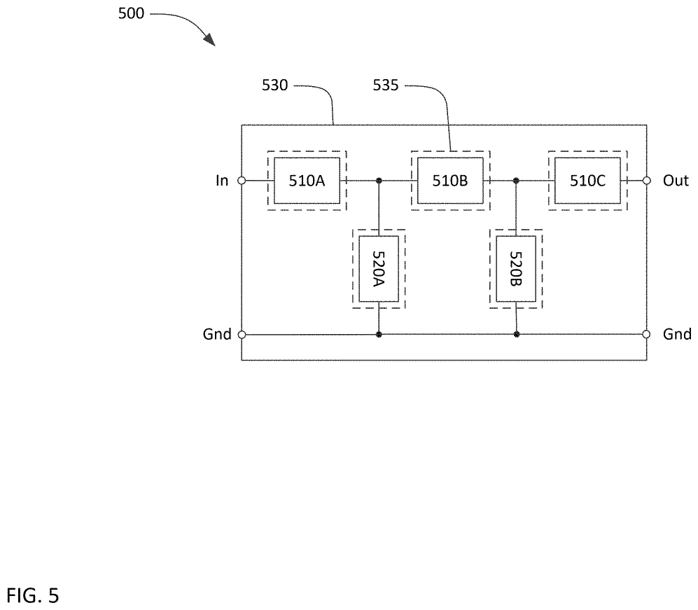

FIG. 5 is a schematic circuit diagram and layout for a high frequency band-pass filter 500 using XBARs. The filter 500 has a conventional ladder filter architecture including three series resonators 510A, 510B, 510C and two shunt resonators 520A, 520B. The three series resonators 510A, 510B, and 510C are connected in series between a first port and a second port. In FIG. 5, the first and second ports are labeled “In” and “Out”, respectively. However, the filter 500 is bidirectional and either port and serve as the input or output of the filter. The two shunt resonators 520A, 520B are connected from nodes between the series resonators to ground. All the shunt resonators and series resonators are XBARs.

The three series resonators 510A, B, C and the two shunt resonators 520A, B of the filter 500 are formed on a single plate 530 of piezoelectric material bonded to a silicon substrate (not visible). Each resonator includes a respective IDT (not shown), with at least the fingers of the IDT disposed over a cavity in the substrate. In this and similar contexts, the term “respective” means “relating things each to each”, which is to say with a one-to-one correspondence. In FIG. 5, the cavities are illustrated schematically as the dashed rectangles (such as the rectangle 535). In this example, each IDT is disposed over a respective cavity. In other filters, the IDTs of two or more resonators may be disposed over a single cavity.

Two or more portions of the piezoelectric plate each may form at least two diaphragms, each diaphragm having an IDT and spanning a respective cavity. In some cases, the two or more portions of the piezoelectric plate are portions of a single piezoelectric plate that spans all of the cavities. In other cases, the two or more portions of the piezoelectric plate are two separate pieces of piezoelectric plate and are separated by an etched trench through the piezoelectric plate. Here, the trench may be etched by patterning all of the plate except where trenches are desired between and to separate or dice each diaphragm from all others. This may be done prior to or after mounting the plate(s) on the substrate. The patterning may use a photoresist as described herein. The etch may be a wet or dry etch such as an etch used to etch the conductor material as described herein.

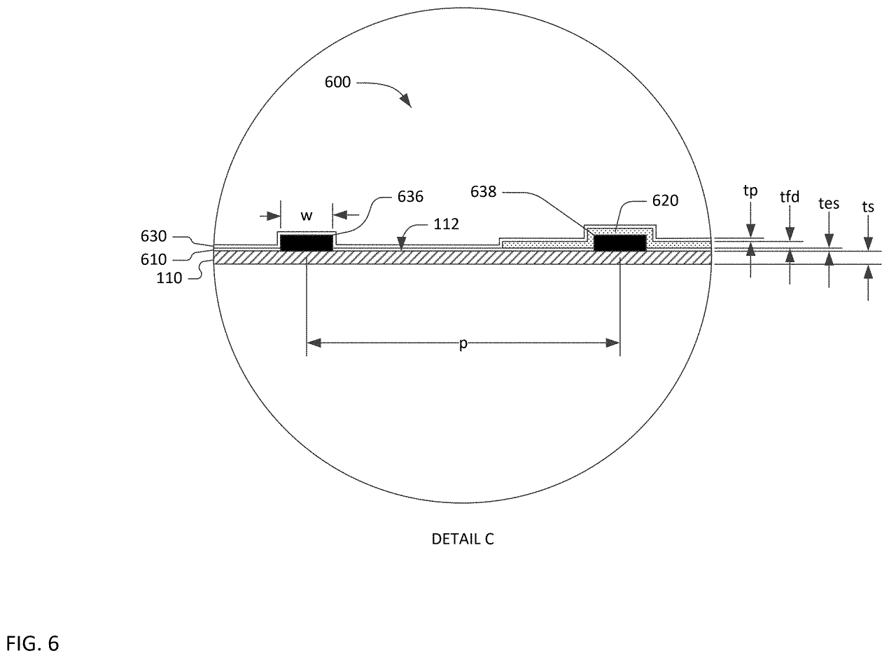

FIG. 6 is an expanded schematic cross-sectional view of a portion of another XBAR device 600 including an etch-stop layer. FIG. 6 shows two IDT fingers 636, 638 formed on a piezoelectric plate 100 which is a portion of the diaphragm of the XBAR device 600.

Traditionally, the IDT fingers, such as the fingers 636, 638, and other conductors of an XBAR device have been formed using a lift-off photolithography process. Photoresist is deposited over the piezoelectric plate and patterned to define the conductor pattern. The IDT conductor layer and, optionally, one or more other layers are deposited in sequence over the surface of the piezoelectric plate. The photoresist may then be removed, which removes, or lifts off, the excess material, leaving the conductor pattern including the IDT fingers. Using a lift-off process does not expose the surface 112 of the piezoelectric plate to reactive chemicals. However, it may be difficult to control the sidewall angle of conductors formed using a lift-off process.

In the XBAR device 600, the IDT fingers 636, 638 are formed using a subtractive or etching process that may provide good control of conductor sidewall angles. One or more metal layers are deposited in sequence over the surface of the piezoelectric plate. The excess metal is then be removed by an anisotropic etch through the conductor layer where it is not protected by a patterned photoresist. The conductor layer can be etched, for example, by anisotropic plasma etching, reactive ion etching, wet chemical etching, and other etching technique.

To protect the surface 112 of the piezoelectric plate 110 from being damaged by the process and chemicals used to etch the conductor layers, the XBAR device 600 includes an etch-stop layer 610 formed on the surface 112 of the piezoelectric plate 100. In FIG. 6, the etch stop layer 610 is shown between but not under the IDT fingers 636, 638. The etch-stop layer 610 may be formed over the entire surface of the piezoelectric plate except under all of the IDT fingers. Alternatively, the etch-stop layer 610 may be formed over the entire surface of the piezoelectric plate except under all conductors.

The etch-stop layer 610 protects the front surface 112 of the piezoelectric plate 110 from the etch process. To this end, the etch-stop layer 610 must be impervious to the etch process or be etched magnitudes slower than the conductor by the etch process. The words “impervious to” have several definitions including “not affected by” and “not allowing etching or to pass through”. Both of these definitions apply to the etch-stop layer 610. The etch-stop layer is not materially affected by the etch process and does not allow the liquid or gaseous etchant used in the etch process to penetrate to the piezoelectric plate 110. The etch-stop layer need not be inert with respect to the etchant but must be highly resistant to the etchant such that a substantial portion of the thickness of the etch stop layer remains after completion of the conductor etch. The remaining etch stop layer 610 is not removed after the IDT fingers 636, 638 and other conductors are formed and becomes a portion of the diaphragm of the XBAR device 600.

The etch-stop layer 610 is formed from an etch-stop material. The etch-stop material must be a dielectric with very low electrical conductivity and low acoustic loss. The etch-stop material must have high adhesion to the surface 112 on which it is deposited. Most importantly, the etch-stop material must be impervious, as previously defined, to the processes and chemicals used to etch the conductors. Alternatively, the etch-stop material must be etched magnitudes slower than the conductor by the processes and chemicals used to etch the conductors. In some cases, a viable etch stop material must withstand the chemistry used to etch IDT material. A material chosen for etch stop purposes may be either etchable with chemistry that does not etch the piezoelectric plate, or be a material that does not degrade the performance of the resonator(s). Suitable etch-stop materials may include oxides such as aluminum oxide and silicon dioxide, sapphire, nitrides including silicon nitride, aluminum nitride, and boron nitride, silicon carbide, and diamond. In some cases, it is an etch stop metal oxide layer.

The XBAR device 600 may include one or more additional dielectric layers that are shown in FIG. 6. A front side dielectric layer 620 may be formed over the IDTs of some (e.g., selected ones) of the XBAR devices in a filter. In FIG. 6, the front side dielectric 620 covers the IDT finger 638 but not the IDT finger 636. In a filter, the front side dielectric may be formed over all of the fingers of some XBAR devices. For example, a front side dielectric layer may be formed over the IDTs of shunt resonators to lower the resonance frequencies of the shunt resonators with respect to the resonance frequencies of series resonators. Some filters may include two or more different thicknesses of front side dielectric over various resonators. The resonance frequency of the resonators can be set thus “tuning” the resonator, at least in part, by selecting a thicknesses of the front side dielectric.

Further, a passivation layer 630 may be formed over the entire surface of the XBAR device 600 except for contact pads where electric connections are made to circuitry external to the XBAR device. The passivation layer is a thin dielectric layer intended to seal and protect the surfaces of the XBAR device while the XBAR device is incorporated into a package. The front side dielectric layer 620 and the passivation layer 630 may be, SiO₂, Si₃N₄, Al₂O₃, some other dielectric material, or a combination of these materials.

Examples of thickness tm tfd, is and tbd are explained for FIG. 2.

Thickness tp may be a thickness that is selected to protect the piezoelectric plate and the metal electrodes from water and chemical corrosion, particularly for power durability purposes. The typical layer thickness tp may range from 10 to 100 nm. The passivation material may consist of multiple oxide and/or nitride coatings such as SiO2 and Si3N4 material.

Examples of thickness tes include between 10 to 30 nm. Thickness tes may be a thickness that is selected to ensure that the etch-stop layer cannot be etched completely through by the etch process used to etch the conductor material that forms the IDT.

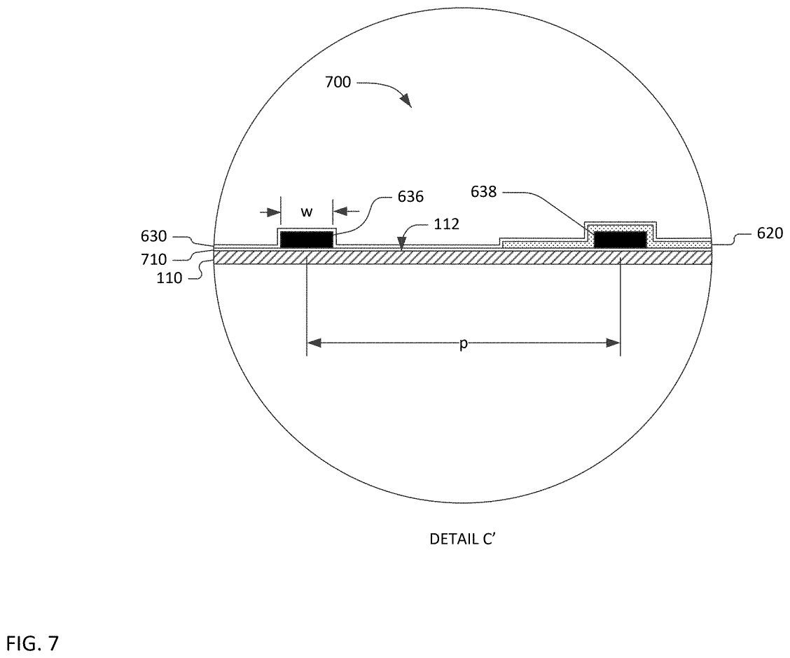

FIG. 7 is an expanded schematic cross-sectional view of a portion of another XBAR device 700 including an etch-stop layer. FIG. 7 shows two IDT fingers 636, 638 formed on a piezoelectric plate 100 which is a portion of the diaphragm of the XBAR device 700. The exception of the etch-stop layer 710, all of the elements of the XBAR device 700 have the same function and characteristics as the corresponding element of the XBAR device 600 of FIG. 6. Descriptions of these elements will not be repeated.

The XBAR device 700 differs from the XBAR device 600 in that the etch stop layer 710 extends over the entire surface 112 of the piezoelectric plate 110 including under the IDT fingers 636, 638. The etch-stop layer 710 may be formed over the entire surface of the piezoelectric plate including under all of the conductors including the IDT fingers. The etch-stop layer 710 is an etch-stop material as previously described.

Description of Methods

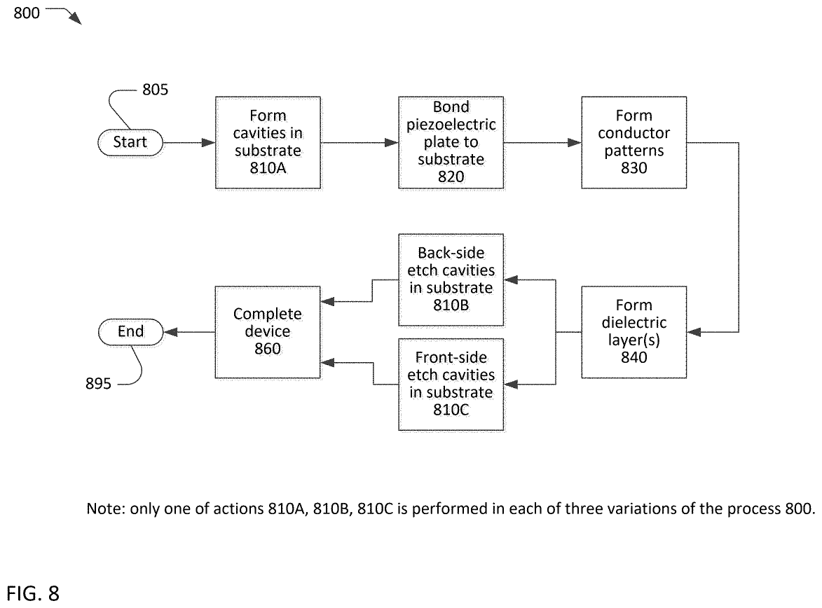

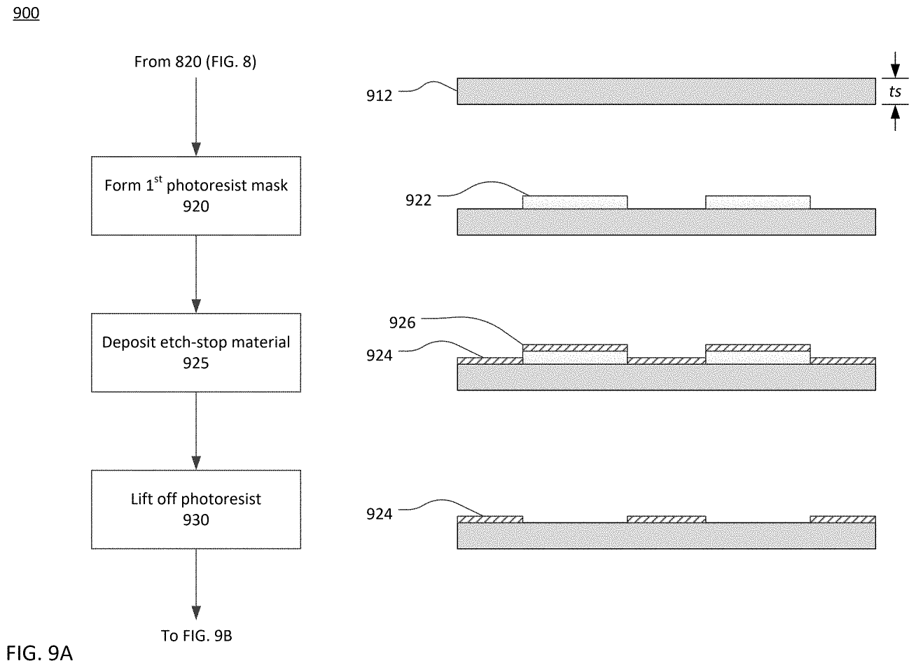

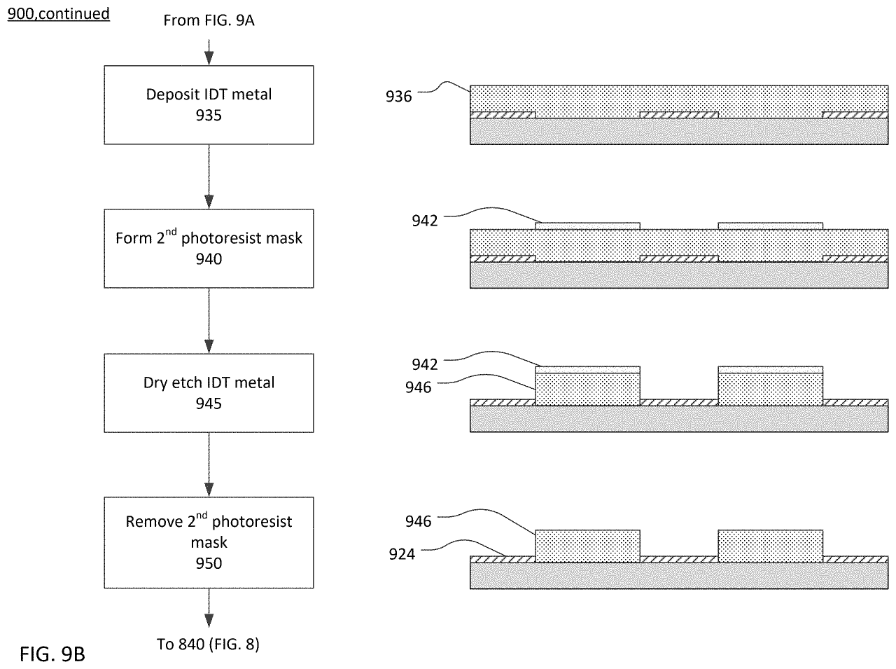

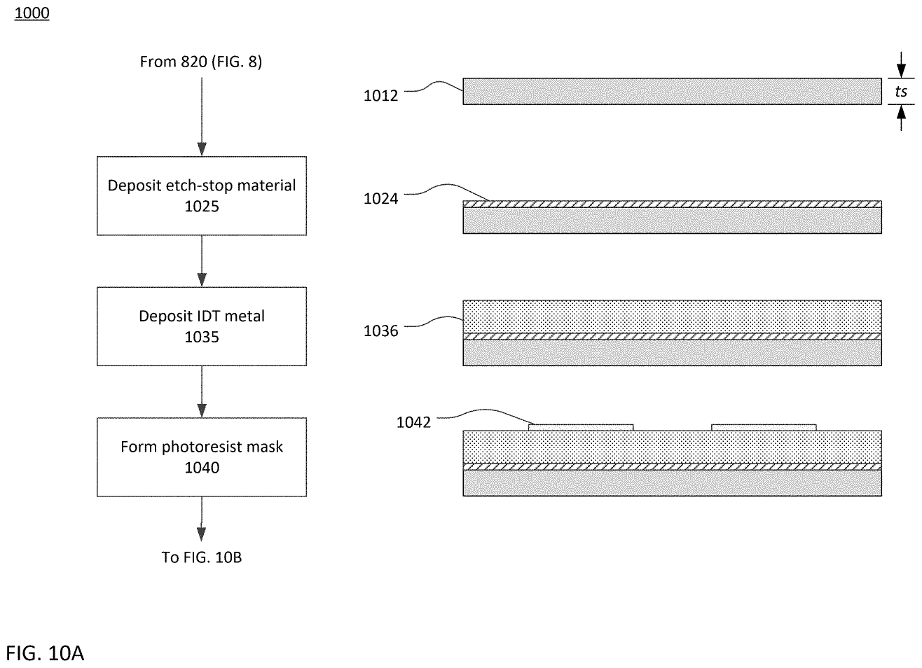

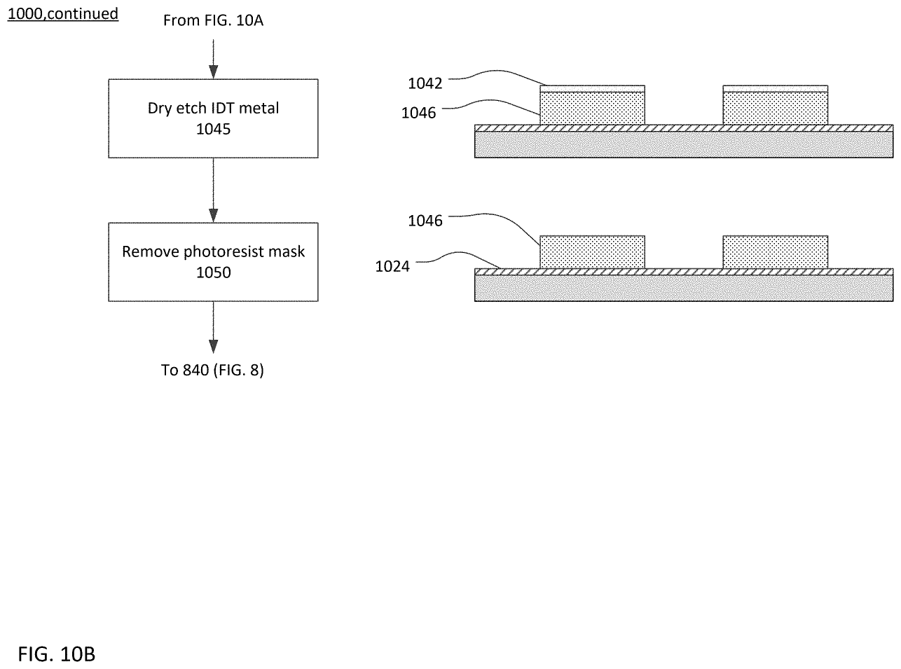

FIG. 8 is a simplified flow chart showing a process 800 for making an XBAR or a filter incorporating XBARs. The process 800 starts at 805 with a substrate 120 and a plate of piezoelectric material 110 and ends at 895 with a completed XBAR or filter. The flow chart of FIG. 8 includes only major process steps. Various conventional process steps (e.g. surface preparation, chemical mechanical processing (CMP), cleaning, inspection, baking, annealing, monitoring, testing, etc.) may be performed before, between, after, and during the steps shown in FIG. 8.

The flow chart of FIG. 8 captures three variations of the process 800 for making an XBAR which differ in when and how cavities are formed in the substrate 120. The cavities may be formed at steps 810A, 810B, or 810C. Only one of these steps is performed in each of the three variations of the process 800.

The piezoelectric plate 110 may be, for example, Z-cut lithium niobate or lithium tantalate as used in the previously presented examples. The piezoelectric plate may be some other material and/or some other cut. The substrate may preferably be silicon. The substrate may be some other material that allows formation of deep cavities by etching or other processing.

In one variation of the process 800, one or more cavities are formed in the substrate 120 at 810A, before the piezoelectric plate is bonded to the substrate at 820. A separate cavity may be formed for each resonator in a filter device. The one or more cavities may be formed using conventional photolithographic and etching techniques. These techniques may be isotropic or anisotropic. Typically, the cavities formed at 810A will not penetrate through the substrate, and the resulting resonator devices will have a cross-section as shown in FIG. 3.

At 820, the piezoelectric plate 110 is bonded to the substrate 120. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers.

A conductor pattern, including IDTs of each XBAR, is formed at 830 by depositing and patterning one or more conductor layer on the front side of the piezoelectric plate. Alternative techniques to form the conductor pattern will be discuss subsequently with respect to FIG. 9 and FIG. 10. In some cases, forming at 830 occurs prior to bonding at 820, such as where the IDT's are formed prior to bonding the plate to the substrate.

At 840, a front-side dielectric layer or layers may be formed by depositing one or more layers of dielectric material on the front side of the piezoelectric plate, over one or more desired conductor patterns of IDT or XBAR devices. The one or more dielectric layers may be deposited using a conventional deposition technique such as sputtering, evaporation, or chemical vapor deposition. The one or more dielectric layers may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different thicknesses of dielectric materials on different portions of the piezoelectric plate. In some cases, depositing at 840 includes depositing a first thickness of at least one dielectric layer over the front-side surface of selected IDTs, but no dielectric or a second thickness less than the first thickness of at least one dielectric over the other IDTs. An alternative is where these dielectric layers are only between the interleaved fingers of the IDTs.

The different thickness of these dielectric layers causes the selected XBARs to be tuned to different frequencies as compared to the other XBARs. For example, the resonance frequencies of the XBARs in a filter may be tuned using different front-side dielectric layer thickness on some XBARs.

As compared to the admittance of an XBAR with tfd=0 (i.e. an XBAR without dielectric layers), the admittance of an XBAR with tfd=30 nm dielectric layer reduces the resonant frequency by about 145 MHz compared to the XBAR without dielectric layers. The admittance of an XBAR with tfd=60 nm dielectric layer reduces the resonant frequency by about 305 MHz compared to the XBAR without dielectric layers. The admittance of an XBAR with tfd=90 nm dielectric layer reduces the resonant frequency by about 475 MHz compared to the XBAR without dielectric layers. Importantly, the presence of the dielectric layers of various thicknesses has little or no effect on the piezoelectric coupling.

In a second variation of the process 800, one or more cavities are formed in the back side of the substrate 120 at 810B. A separate cavity may be formed for each resonator in a filter device. The one or more cavities may be formed using an anisotropic or orientation-dependent dry or wet etch to open holes through the back-side of the substrate to the piezoelectric plate. In this case, the resulting resonator devices will have a cross-section as shown in FIG. 1.

In a third variation of the process 800, one or more cavities in the form of recesses in the substrate 120 may be formed at 810C by etching the front side of the substrate using an etchant introduced through openings in the piezoelectric plate. A separate cavity may be formed for each resonator in a filter device. The one or more cavities may be formed using an isotropic or orientation-independent dry or wet etch that passes through holes in the piezoelectric plate and etches the front-side of the substrate. The one or more cavities formed at 810C will not penetrate completely through the substrate, and the resulting resonator devices will have a cross-section as shown in FIG. 3.

In all variations of the process 800, the filter or XBAR device is completed at 860. Actions that may occur at 860 include depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 860 is to tune the resonant frequencies of the resonators within a filter device by adding or removing metal or dielectric material from the front side of the device. After the filter device is completed, the process ends at 895. FIGS. 6 and 7 may show examples of the fingers of selected IDTs after completion at 860.

FIG. 9A and FIG. 9B are collectively a flow chart of a process 900 for forming a conductor pattern using dry etching and an etch-stop layer. The process 900 is or is included in the forming of conductor patterns at 830 of process 800. Process 900 is a subtractive or etching process that provides good control of conductor sidewall angles for the conductor pattern (e.g., of the IDT and/or fingers herein).

The process 900 starts at 920 with a plate of piezoelectric material 912 and ends at 950 with a completed XBAR conductor pattern 946 formed on the piezoelectric material plate 912. Piezoelectric plate 912 at 920 may be any of plates 110, 310 and/or 410. The completed XBAR conductor pattern 946 on the plate at 950 may be a conductor pattern that is or that includes the IDT patterns and/or fingers described herein for XBAR devices.

The flow chart of FIG. 9 includes only major process steps. Various conventional process steps (e.g. surface preparation, chemical mechanical processing (CMP), cleaning, inspection, baking, annealing, monitoring, testing, etc.) may be performed before, between, after, and during the steps shown in FIG. 9.

At 920 a first patterned photoresist mask 922 is formed over piezoelectric plate 912. The photoresist mask 922 may be a patterned lithography mask that is formed over areas of the piezoelectric plate 912 where the etch stop layer is not desired. These may be areas or locations where the desired conductor pattern of the IDT or fingers are to be formed. The photoresist mask 922 may be deposited over the piezoelectric plate and patterned to define the conductor pattern where the photoresist mask 922 exists after patterning.

At 925 an etch stop material 926 is deposited over the over the piezoelectric plate 912 and over the photoresist mask 922. The etch stop material 926 may be blanket deposited over all of the exposed top surfaces of the plate and mask to form an etch-stop layer. This etch-stop layer may include the etch stop material in the pattern of etch-stop layer 610 as well as etch stop material on the photoresist mask 922. The etch stop material 926 may be a material and/or be deposited as described for etch-stop layer 610.

At 930 the first photoresist mask 922 is removed. At 930 the photoresist mask 922 may then be removed, which removes, or lifts off, the etch stop material 926 which was deposited on the photoresist mask 922, thus leaving the pattern of etch-stop layer 610 on the piezoelectric plate 912. The first photoresist mask 922 is removed using a process that does not expose the surface of the piezoelectric plate 912 to reactive chemicals or a process that will damage or etch the piezoelectric plate 912.

At 935 IDT conductor material 936 is deposited over the etch stop material 924 and over the piezoelectric plate 912 where the first photoresist mask 922 was removed. The conductor material may be an electronically conductive material and/or material used to form a conductor pattern as noted herein. Depositing at 935 may be blanket depositing one or more metal layers in sequence over the top surfaces of the etch stop material 924 and the exposed piezoelectric plate 912. The IDT conductor material 936 may be blanket deposited over all of the exposed top surfaces of the etch-stop layer 924 and of the piezoelectric plate 912.

At 940 a patterned second photoresist mask 942 is formed over the IDT conductor material 936. The photoresist mask 942 may be a patterned lithography mask that is formed over areas of the IDT conductor material 936 where the IDT conductor material 946 is desired. These may be areas or locations where the desired conductor pattern of the IDT or fingers are to be formed. The photoresist mask 942 may be blanket deposited over the IDT conductor material 936 and then patterned to define the conductor pattern 946 where the photoresist mask 942 exists after patterning.

The patterned second photoresist mask 942 may function like an etch stop in that it will be impervious to and/or be etch magnitudes slower than the conductor material by the processes and chemicals used to etch the conductor material 936. Suitable photoresist materials may include oxides such as a light sensitive material, a light-sensitive organic material (e.g., a photopolymeric, photodecomposing, or photocrosslinking photoresist), an oxide or a nitride.

At 945 IDT conductor material 936 is dry etched and removed by an anisotropic etch through the conductor where it is not protected by the second photoresist mask 942, thus forming conductor pattern 946. The conductor layer 936 can be etched, for example, by an anisotropic plasma etching, reactive ion etching, wet chemical etching, and other etching techniques. The etch may be a highly anisotropic, high-energy etch process that can damage (via chemical etch or physical sputtering) the piezoelectric layer where that layer is exposed to the etch.

The dry etch etches or removes the conductor over and to the etch stop material 924. Both, the second photoresist mask 942 and the etch stop material 924 are impervious, as previously defined, to the processes and chemicals used to etch the conductors. Alternatively, they are etched magnitudes slower than the conductor material by the processes and chemicals used to etch the conductors. Thus, this anisotropic etch does not remove the conductor material 936 under the second photoresist mask 942 and does not remove the etch stop material 924 since they are impervious and/or etched magnitudes slower. The conductor material 936 remaining under the second photoresist mask 942 and on the piezoelectric plate 912 is the conductor pattern desired for the IDT and/or fingers.

At 950 the second photoresist mask 942 is removed from the top surface of the conductor material 936. This leaves the pattern of desired conductor material 946 deposited directly onto the piezoelectric plate 912 and the etch stop material 924 between but not under the conductor material. The second photoresist mask 942 is removed using a process that does not expose the surface of the conductor to reactive chemicals or a process that will damage or etch the conductor material 946.

After removing at 950, the remaining desired conductor material 96 may be or include the IDT conductor and/or fingers described herein. It may be the conductor material in the XBAR device 600, such as the IDT fingers 636, 638. The remaining etch stop material 924 may be or be include etch stop layer 610.

FIG. 10A and FIG. 10B are collectively a flow chart of another process 1000 for forming a conductor pattern using dry etching and an etch-stop layer. The process 1000 is or is included in the forming of conductor patterns at 830 of process 800. Process 1000 is a subtractive or etching process that provides good control of conductor sidewall angles for the conductor pattern (e.g., of the IDT and/or fingers herein).

The process 1000 starts at 1025 with a plate of piezoelectric material 1012 and ends at 1050 with a completed XBAR conductor pattern 1046 formed on the piezoelectric material plate 1012. Piezoelectric plate 1012 at 1025 may be any of plates 110, 310 and/or 410. The completed XBAR conductor pattern 1046 on the plate at 1050 may be a conductor pattern that is or that includes the IDT patterns and/or fingers described herein for XBAR devices.

The flow chart of FIG. 10 includes only major process steps. Various conventional process steps (e.g. surface preparation, chemical mechanical processing (CMP), cleaning, inspection, baking, annealing, monitoring, testing, etc.) may be performed before, between, after, and during the steps shown in FIG. 10.

At 1025 an etch stop material 1024 is deposited over the over the piezoelectric plate 1012. The etch stop material 1024 may be blanket deposited over all of the exposed top surfaces of the plate to form an etch-stop layer. The etch stop material 1024 may be a material and/or be deposited as described for etch-stop layer 610.

At 1035 IDT conductor material 1036 is deposited over the etch stop material 1024. The IDT conductor material 1036 may be blanket deposited over all of the exposed top surfaces of the etch-stop layer. Depositing at 1035 may be depositing one or more metal layers in sequence over the top surfaces of the etch stop material 1024.

At 1040 a patterned photoresist mask 1042 is formed over the IDT conductor material 1036. The photoresist mask 1042 may be a patterned lithography mask that is formed over areas of the IDT conductor material 1036 where the IDT conductor material 1046 is desired. These may be areas or locations where the conductor pattern of the IDT or fingers are to be formed. The photoresist mask 1042 may be blanket deposited over the IDT conductor material 1036 and then patterned to define the conductor pattern 1046 where the photoresist mask 1042 exists after patterning.

The patterned photoresist mask 1042 may function like an etch stop in that it will be impervious to and/or be etch magnitudes slower than the conductor material by the processes and chemicals used to etch the conductor material 1036. Suitable photoresist materials may include oxides such as a light sensitive material, a light-sensitive organic material (e.g., a photopolymeric, photodecomposing, or photocrosslinking photoresist), an oxide or a nitride.

At 1045 IDT conductor material 1036 is dry etched and removed by an anisotropic etch through the conductor where it is not protected by the photoresist mask 1042, thus forming conductor pattern 1046. The conductor layer 1036 can be etched, for example, by an anisotropic plasma etching, reactive ion etching, wet chemical etching, and other etching techniques. The etch may be a highly anisotropic, high-energy etch process that can damage (via chemical etch or physical sputtering) the piezoelectric layer where that layer is exposed to the etch.

The dry etch etches or removes the conductor over and to the etch stop material 1024. Both, the photoresist mask 1042 and the etch stop material 1024 are impervious, as previously defined, to the processes and chemicals used to etch the conductors. Alternatively, they are etched magnitudes slower than the conductor material by the processes and chemicals used to etch the conductors. Thus, this anisotropic etch does not remove the conductor material 1036 under the second photoresist mask 1042 and does not remove the etch stop material 1024 since they are impervious and/or etched magnitudes slower. The conductor material 1036 remaining under the second photoresist mask 1042 and on the etch stop material 1024 is the conductor pattern desired for the IDT and/or fingers.

At 1050 the photoresist mask 1042 is removed from the top surface of the conductor material 1036. This leaves the pattern of desired conductor material 1046 deposited directly onto the etch stop material 1024 between and under the conductor material 1046. The photoresist mask 922 is removed using a process that does not expose the surface of the conductor material 1046 to reactive chemicals or a process that will damage or etch the conductor material 1046.

After removing at 1050, the remaining desired conductor material 1046 may be or include the IDT conductor and/or fingers described herein. It may be the conductor material in the XBAR device 700, such as the IDT fingers 736 and 738. The remaining etch stop material 1024 may be or be include etch stop layer 710.

Using the subtractive or etching of each of processes 900 and 1000 provides better control of conductor sidewall angles of the desired conductor material than a lift-off process. In some cases, processes 900 and 1000 provide a predefined deposit-etched IDT with sharp sidewall angles by using a highly anisotropic, high-energy etch process that may damage (via chemical etch or physical sputtering) the piezoelectric layer, and by protecting the piezoelectric layer with a thin layer of insulating etch stop metal oxide layer that is deposited over it. By using the highly anisotropic, high-energy etch process and etch stop layer the processes 900 and 1000 allow for better resolution of the IDTs as well as sharper vertical wall angle of the IDTs.

Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An acoustic resonator device comprising:
a substrate having a surface;
a single-crystal piezoelectric plate having front and back surfaces, the back surface of the piezoelectric plate bonded to a front surface of the substrate;
an interdigital transducer (IDT) formed on the front surface of the single-crystal piezoelectric plate, the IDT having interleaved fingers disposed on a diaphragm spanning a cavity in the substrate; and
an etch-stop layer formed on the front surface of the piezoelectric plate between the interleaved fingers, a portion of the piezoelectric plate and the etch-stop layer forming the diaphragm, wherein
the etch-stop layer is impervious to an etch process used to form the interleaved fingers.

2. The device of claim 1, wherein the etch-stop layer is formed on the front surface of the piezoelectric plate between but not under the interleaved fingers,

3. The device of claim 1, wherein the etch-stop layer is formed on the front surface of the piezoelectric plate between and under the interleaved fingers,

4. The device of claim 1, wherein the single-crystal piezoelectric plate is one of lithium niobate and lithium tantalate; and wherein the etch-stop layer is one of an oxide, sapphire, a nitride, silicon carbide, and diamond.

5. The device of claim 4, wherein the etch-stop layer is aluminum oxide.

6. The device of claim 4, wherein the etch-stop layer is a high thermal conductivity material selected from aluminum nitride, boron nitride, and diamond.

7. The device of claim 1, further comprising:
a front-side dielectric layer on the etch stop layer and on the interleaved fingers, wherein the diaphragm includes the piezoelectric plate, the front-side dielectric layer, and the etch-stop layer.

8. The device of claim 7, wherein the front-side dielectric layer is SiO₂, Si₃N₄, or Al₂O₃.

9. The device of claim 7, further comprising:
passivation layer over the front-side dielectric layer.

10. The device of claim 1, wherein the IDT and piezoelectric plate are configured such that a radio frequency signal applied to the IDT excites a shear primary acoustic mode within the piezoelectric plate, and wherein a direction of acoustic energy flow of the shear primary acoustic mode is substantially orthogonal to the front and back surfaces of the single-crystal piezoelectric plate.

11. A filter device, comprising:
a substrate having a front surface;
a single-crystal piezoelectric plate having front and back surfaces, the back surface of the piezoelectric plate bonded to the front surface of the substrate;
a conductor pattern formed on the front surface of the piezoelectric plate, the conductor pattern including a plurality of interdigital transducers (IDTs) of a respective plurality of acoustic resonators including a shunt resonator and a series resonator, interleaved fingers of each of the plurality of IDTs disposed on a respective diaphragm of one or more diaphragms spanning respective cavities in the substrate;
an etch-stop layer formed on the front surface of the piezoelectric plate between interleaved fingers of the IDTs, portions of the single-crystal piezoelectric plate and the etch-stop layer forming the one or more diaphragms, wherein
the etch-stop layer is impervious to an etch process used to form the interleaved fingers.

12. The filter device of claim 11, further comprising:
a frequency setting dielectric layer disposed on a front surface of the etch-stop layer between the interleaved fingers of the IDT of the shunt resonator.

13. The filter device of claim 12, wherein
the frequency setting dielectric layer is a first dielectric layer that has a first thickness that is greater than a second thickness of a second dielectric layer deposited between the fingers of the IDT of the series resonator,
a resonance frequency of the shunt resonator is set, at least in part, by the first thickness, and
a resonance frequency of the series resonator is set, at least in part, by the second thickness.

14. The filter device of claim 13, wherein a difference between the first thickness and the second thickness is sufficient to set the resonance frequency of the shunt resonator at least 145 MHz lower than the resonance frequency of the series resonator.

15. The filter device of claim 11, wherein at least two portions of the piezoelectric plate form at least two diaphragms, each diaphragm spanning a respective one of the at least two cavities.

16. The filter device of claim 11, wherein the at least two portions of the piezoelectric plate are two separate pieces of piezoelectric plate and are separated by an etched trench through the piezoelectric plate.

17. The filter device of claim 11, wherein the etch-stop layer is formed on the front surface of the piezoelectric plate between but not under the interleaved fingers.

18. The filter device of claim 11, wherein the etch-stop layer is formed on the front surface of the piezoelectric plate between and under the interleaved fingers.

19. A filter device, comprising:
a substrate having a front surface;
a piezoelectric plate having front and back surfaces, the back surface of the piezoelectric plate coupled to the front surface of the substrate;
a conductor pattern of a conductor material formed over the front surface of the piezoelectric plate, the conductor pattern including a plurality of interdigital transducers (IDTs) of a respective plurality of acoustic resonators including at least one shunt resonator and at least series resonator, interleaved fingers of each of the plurality of IDTs disposed on a respective diaphragm of one or more diaphragms spanning respective cavities in the substrate;
an etch-stop layer formed on the front surface of each IDT between interleaved fingers of the IDTs, the one or more diaphragms including portions of the single-crystal piezoelectric plate and the etch-stop layer, wherein the etch-stop layer is a material selected to be impervious to at least one etch process capable of etching the conductor material.

20. The filter device of claim 19, wherein the at least one etch process is a highly anisotropic, high-energy chemical etch process or physical sputtering etch process.
